(19) United States
(12) Patent Application Publication
(10) Pub. No.: US 2022/0367253 A1
(43) Pub. Date: Nov. 17, 2022

(54) INTERCONNECT STRUCTURE AND METHODS OF FORMING THE SAME

(71) Applicant: TAIWAN SEMICONDUCTOR MANUFACTURING COMPANY, LTD., Hsinchu (TW)

(72) Inventors: Chien-Han CHEN, Nantou (TW); Da-Wei LIN, New Taipei (TW); Yi Tang CHEN, Hsinchu (TW); Chien-Chih CHIU, Tainan (TW)

(21) Appl. No.: 17/479,203

(22) Filed: Sep. 20, 2021

Related U.S. Application Data
(60) Provisional application No. 63/188,030, filed on May 13, 2021.

(51) Int. Cl. H01L 21/768; H01L 23/522

(52) U.S. Cl. CPC H01L 21/76816; H01L 23/5226; H01L 21/31122

(57) ABSTRACT

A method for forming an interconnect structure is described. In some embodiments, the method includes forming a mask structure on a dielectric layer, and the mask structure includes a first layer, a second layer disposed on the first layer, and a third layer disposed on the second layer. The method further includes forming first openings having first dimensions in the first layer and forming a multilayer structure over the first layer. The multilayer structure includes a bottom layer disposed in the first openings and over the first layer, a middle layer disposed on the bottom layer, and a photoresist layer disposed on the middle layer. The method further includes forming second openings having second dimensions in the bottom layer to expose portions of the dielectric layer, and the second dimensions are smaller than the first dimensions. The method further includes extending the second openings into the dielectric layer.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. For example, as the aspect ratio of conductive features in the dielectric material in the back-end-of-line (BEOL) interconnect structure gets higher, the process for forming conductive vias gets more arduous. Therefore, improved methods of forming the interconnect structure are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of one of various stages of manufacturing a semiconductor device structure, in accordance with some embodiments.

FIG. 1B is a cross-sectional side view of the stage of manufacturing the semiconductor device structure taken along line A-A of FIG. 1A, in accordance with some embodiments.

FIG. 2 is a cross-sectional side view of a stage of manufacturing the semiconductor device structure, in accordance with some embodiments.

FIGS. 3A-3J are cross-sectional side views of various stages of manufacturing an interconnect structure, in accordance with some embodiments.

FIG. 4 is a cross-sectional top view of the interconnect structure along cross-section A-A shown in FIG. 3G, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

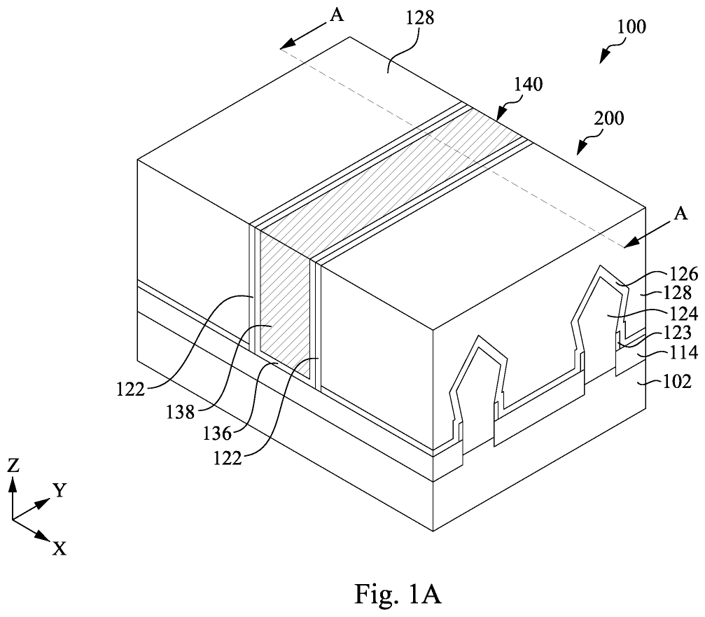

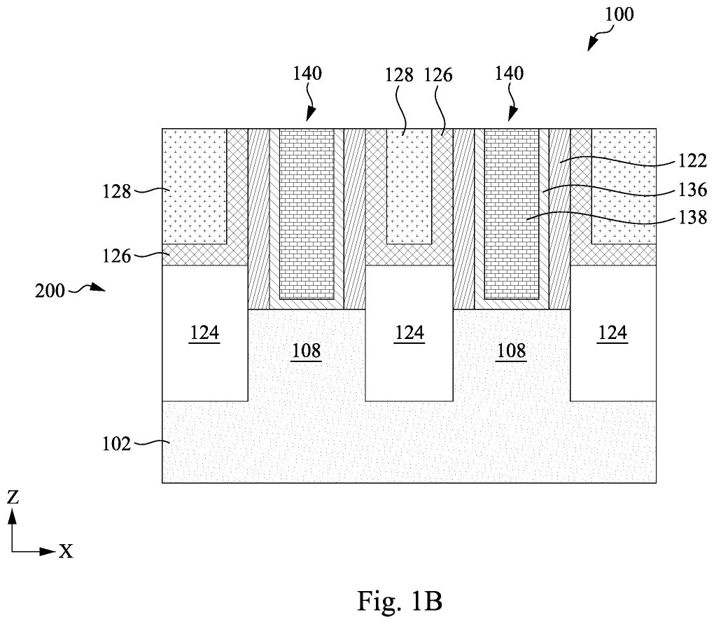

FIGS. 1A and 1B illustrate a stage of manufacturing a semiconductor device structure 100. As shown in FIGS. 1A and 1B, the semiconductor device structure 100 includes a substrate 102 and one or more devices 200 formed on the substrate 102. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include one or more buffer layers (not shown) on the surface of the substrate 102. The buffer layers can serve to gradually change the lattice constant from that of the substrate to that of the source/drain regions. The buffer layers may be formed from epitaxially grown crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP. In one embodiment, the substrate 102 includes SiGe buffer layers epitaxially grown on the silicon substrate 102. The germanium concentration of the SiGe buffer layers may increase from 30 atomic percent germanium for the bottom-most buffer layer to 70 atomic percent germanium for the top-most buffer layer.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the devices 200 may be any suitable devices, such as transistors, diodes, imaging sensors, resistors, capacitors, inductors, memory cells, or a combination thereof. In some embodiments, the devices 200 are transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device 200 formed on the substrate 102 is a FinFET, which is shown in FIGS. 1A and 1B. The device 200 includes source/drain (S/D) regions 124 and gate stacks 140 (only one is shown in FIG. 1A). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. As shown in FIG. 1B, two gate stacks 140 are formed on the substrate 102. In some embodiments, more than two gate stacks 140 are formed on the substrate 102. Channel regions 108 are formed between S/D regions 124 serving as source regions and S/D regions 124 serving as drain regions.

The S/D regions 124 may include a semiconductor material, such as Si or Ge, a III-V compound semiconductor, a II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions 108 may include one or more semiconductor materials, such as Si, Ge, GeSn, SiGe, GaAs, InSb, GaP, GaSb, InAlAs, InGaAs, GaSbP, GaAsSb, GaN, GaP, or InP. In some embodiments, the channel regions 108 include the same semiconductor material as the substrate 102. In some embodiments, the devices 200 are FinFETs, and the channel regions 108 are a plurality of fins disposed below the gate stacks 140. In some embodiments, the devices 200 are nanostructure transistors, and the channel regions 108 are surrounded by the gate stacks 140.

As shown in FIGS. 1A and 1B, each gate stack 140 includes a gate electrode layer 138 disposed over the channel region 108 (or surrounding the channel region 108 for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. Each gate stack 140 may further include a gate dielectric layer 136 disposed over the channel region 108. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layers 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique.

As shown in FIG. 1A, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

As shown in FIGS. 1A and 1B, a contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

A conductive contact (not shown) may be disposed in the ILD layer 128 and over the S/D region 124. The conductive contact may be electrically conductive and include a material having one or more of Ru, Mo, Co, Ni. W, Ti, Ta, Cu, Al, TiN or TaN, and the conductive contact may be formed by any suitable method, such as electro-chemical plating (ECP), or PVD. A silicide layer (not shown) may be disposed between the conductive contact and the S/D region 124.

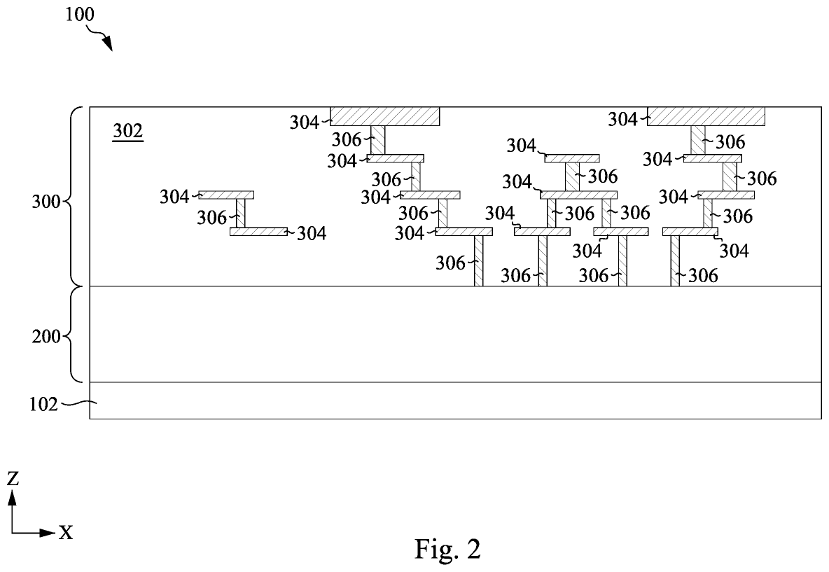

The semiconductor device structure 100 may further includes an interconnection structure 300 disposed over the devices 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices 200 disposed below. The conductive features 306 provide vertical electrical routing from the devices 200 to the conductive features 304 and between conductive features 304. For example, the bottom-most conductive features 306 of the interconnection structure 300 may be electrically connected to the conductive contacts disposed over the S/D regions 124 (FIG. 1B) and the gate electrode layer 138 (FIG. 1B). The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a dielectric material having a k value ranging from about 1 to about 5.

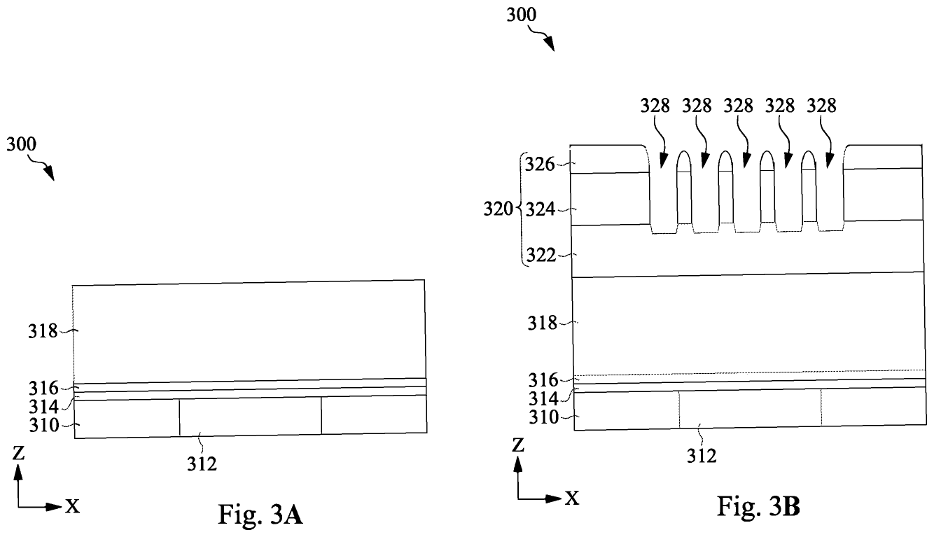

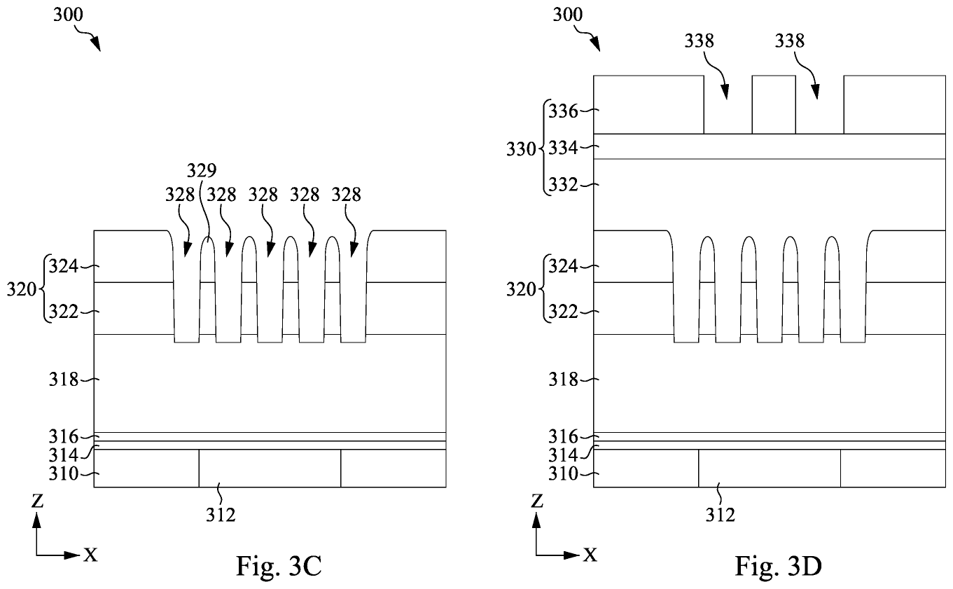

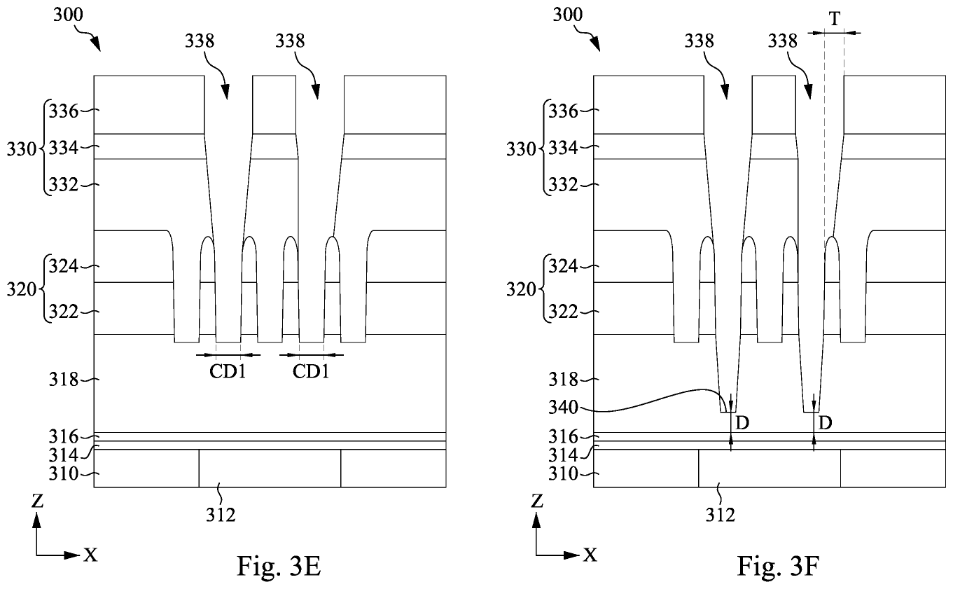

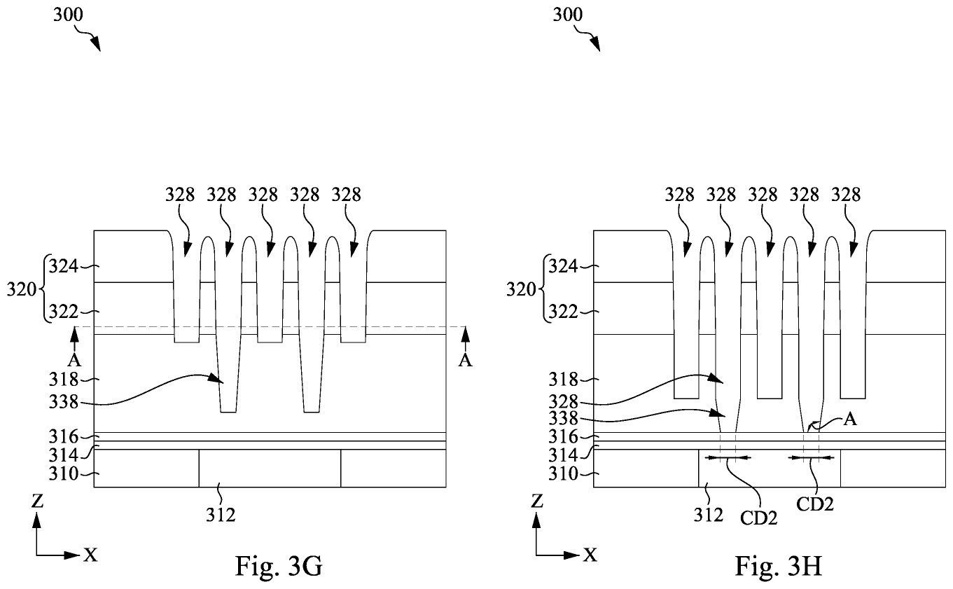

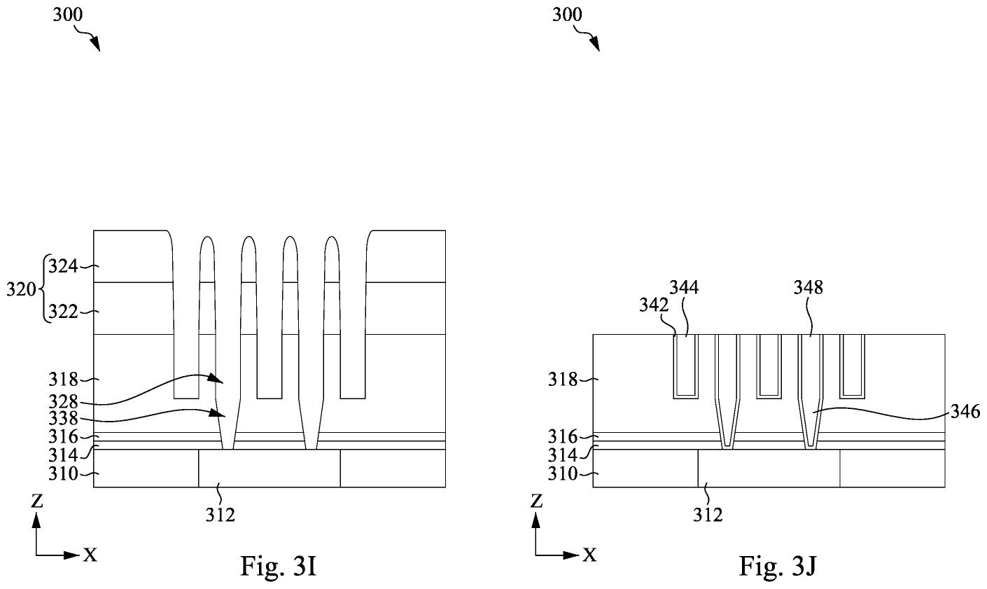

FIGS. 3A-3J are cross-sectional side views of various stages of manufacturing the interconnect structure 300, in accordance with some embodiments. As shown in FIG. 3A, the interconnect structure 300 includes a dielectric layer 310, which may be an ILD layer or an IMD layer. For example, the dielectric layer 310 may be the ILD layer 128 (FIGS. 1A and 1B) or the IMD layer 302 (FIG. 2). The dielectric layer 310 may include the same material as the ILD layer 128 or the IMD layer 302. In some embodiments, the dielectric layer 310 includes a low-k dielectric material, such as SiOCH. The dielectric layer 310 may be formed by CVD, FCVD, ALD, spin coating, or other suitable process. The dielectric layer 310 includes one or more conductive features 312 (only one is shown) disposed in the dielectric layer 310. The conductive feature 312 may include an electrically conductive material, such as Cu, Co, Ru, Mo, Cr, W, Mn, Rh, Ir, Ni, Pd, Pt, Ag, Au, Al, alloys thereof, or other suitable material. In some embodiments, the conductive feature 312 includes a metal. The conductive feature 312 may be formed by PVD, CVD, ALD, or other suitable process. In some embodiments, the conductive feature 312 may be the conductive contact disposed in the ILD layer 128 or the conductive feature 304 or 306 disposed in the IMD layer 302. In some embodiments, the conductive feature 312 includes a barrier layer (not shown) disposed between the dielectric layer 310 and the electrically conductive material of the conductive feature 312. The barrier layer may include an electrically conductive material, such as a metal or metal nitride.

A first etch stop layer 314 is disposed on the dielectric layer 310. The first etch stop layer 314 may include a nitrogen-containing material or an oxygen-containing material. For example, the first etch stop layer 314 may be a nitride or an oxide, such as silicon nitride, a metal nitride, silicon oxide, or a metal oxide. In some embodiments, the first etch stop layer 314 includes the same material as the CESL 126 (FIGS. 1A and 1B). The first etch stop layer 314 may be formed by any suitable process, such as CVD, PECVD, ALD, PEALD, or any suitable process. In some embodiments, the first etch stop layer 314 is a conformal layer formed by ALD. A second etch stop layer 316 is disposed on the first etch stop layer 314. The second etch stop layer 316 may include a nitrogen-containing material or an oxygen-containing material, such as a nitride or an oxide, for example silicon nitride, metal nitride, silicon oxide, or metal oxide. The second etch stop layer 316 may be formed by the same process as the first etch stop layer 314. The second etch stop layer 316 includes a different material as the first etch stop layer 314. In some embodiments, the second etch stop layer 316 is not present. In some embodiments, a third etch stop layer (not shown) may be disposed on the second etch stop layer 316.

Another dielectric layer 318 is disposed on the second etch stop layer 316. The dielectric layer 318 may include the same material as the dielectric layer 310 and may be formed by the same process as the dielectric layer 310.

As shown in FIG. 3B, a mask structure 320 is disposed on the dielectric layer 318. The mask structure 320 includes a first layer 322, a second layer 324 disposed on the first layer 322, and a third layer 326 disposed on the second layer 324. The first layer 322 and the third layer 326 may include the same material, and the second layer 324 includes a different material as the first and third layers 322, 326. The first layer 322 and the dielectric layer 318 include different materials. In some embodiments, the first and third layers 322, 326 each includes an oxide, such as a silicon dioxide, which is different from the low-k material, such as SiOCH, of the dielectric layer 318. The second layer 324 may include a nitride, such as a metal nitride, for example titanium nitride (TiN).

As shown in FIG. 3B, openings 328 are formed in the third layer 326 and the second layer 324. The openings 328 may be formed by two etch processes. In some embodiments, the openings 328 are formed by two dry etch processes using inductively coupled plasma (ICP). For example, a first ICP etch process is performed to form the openings 328 in the third layer 326, and a second ICP etch process is performed to extend the openings 328 into the second layer 324. The etchants used in the two ICP etch processes are different in order to provide etch selectivity of the second and third layers 324, 326. The ICP etch process provides high etch rate due to high radical density. Thus, as shown in FIG. 3B, when forming the openings 328 in the second layer 324, portions of the first layer 322 may be removed. Therefore, the openings 328 may be extended into portions of the first layer 322.

As shown in FIG. 3C, the openings 328 are extended into the first layer 322 to expose the dielectric layer 318. The openings 328 are extended into the first layer 322 by removing portions of the first layer 322. The removal of the portions of the first layer 322 may be performed by a dry etch process using capacitively coupled plasma (CCP). Unlike the dry etch process using ICP, the CCP etch process has less radical density, which reduces the chance of over etching. As a result, the dielectric layer 318 is not substantially affected. In some embodiments, the CCP etch process may be a dual-frequency etch process having a high RF frequency ranging from about 30 MHz to about 50 MHz and a low RF frequency ranging from about 12 MHz to about 15 MHz. In some embodiments, the high RF frequency is about 40 MHz, and the low RF frequency is about 12.88 MHz. The RF power of the high RF frequency may range from about 200 W to about 1000 W, and the RF power of the low RF frequency may range from about 50 W to about 500 W. Because the openings 328 in the first layer 322 are trenches, the majority of the CCP etch process uses high RF frequency, such as about 90 percent of the time high RF frequency is used. The chamber pressure of the CCP etch process ranges from about 10 mT to about 80 mT, and the process temperature ranges from about 0 degrees Celsius to about 50 degrees Celsius. The etchant used in the CCP etch process may include CₓF_{y}, where x and y are integers. For example, C₄F₆ is used as an etchant. Additional gases may be used in the etch process, such as N₂, O₂, Ar, H₂, or CHₓF_{y}. These gases may be used in addition to CₓF_{y} or to replace CₓF_{y}. The flow rate of CₓF_{y} may range from about 20 sccm to about 50 sccm, the flow rate of N₂ may range from about 0 sccm to about 100 sccm, the flow rate of O₂ may range from about 0 sccm to about 25 sccm, the flow rate of Ar may range from about 600 sccm to about 1200 sccm, the flow rate of H₂ may range from about 0 sccm to about 100 sccm, and the flow rate of CHₓF_{y} may range from about 0 sccm to about 100 sccm. The DC self bias of the CCP etch process may range from about 0 to about 500 V. The CCP etch process may also have a line center and edge trench depth bias of less than 20 Angstroms.

With the above mentioned CCP etch process, the openings 328 are extended in the first layer 322 and to expose the dielectric layer 318 without over etching of the dielectric layer 318. As shown in FIG. 3C, the third layer 326 (FIG. 3B) is removed as a result of the CCP etch process, because the third layer 326 includes the same material as the first layer 322. Furthermore, the remaining portions of the second layer 324 between adjacent openings 328 have a curved top portion 329. The curved top portions 329 help with subsequent via opening forming in the dielectric layer 318.

As shown in FIG. 3D, a multilayer structure 330 is disposed on the second layer 324. The multilayer structure 330 includes a bottom layer 332, a middle layer 334 disposed on the bottom layer 332, and a photoresist layer 336 disposed on the middle layer 334. In some embodiments, the multilayer structure 330 is a tri-layer photoresist. The bottom layer 332 and the middle layer 334 are made of different materials such that the optical properties and/or etching properties of the bottom layer 332 and the middle layer 334 are different from each other. In some embodiments, the bottom layer 332 may be an absorber layer, such as a chromium layer. The bottom layer 332 may be disposed in the openings 328 (FIG. 3C) and on the exposed portions of the dielectric layer 318. The middle layer 334 may be a silicon-rich layer designed to provide an etch selectivity between the middle layer 334 and the bottom layer 332. The photoresist layer 336 may be a chemically amplified photoresist layer and can be a positive tone photoresist or a negative tone photoresist. The photoresist layer 336 may include a polymer, such as phenol formaldehyde resin, a poly(norbornene)-co-malaic anhydride (COMA) polymer, a poly(4-hydroxystyrene) (PHS) polymer, a phenol-formaldehyde (hakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The photoresist layer 336 may be formed by spin-on coating.

As shown in FIG. 3D, the photoresist layer 336 is patterned. The patterning of the photoresist layer 336 may include exposing the photoresist layer 336 to an exposure light/beam through a photo mask (not shown). The exposure light/beam can be deep ultra violet (DUV) light, such as KrF excimer laser light and ArF excimer laser light, extreme ultra violet (EUV) light having a wavelength around 13.5 nm, an X-ray, and/or electron beam. In some embodiments, multiple exposure processes are performed. After the exposure process, a developing process is performed to form the patterned photoresist layer 336. As a result of the patterning process, openings 338 are formed in the photoresist layer 336, and portions of the middle layer 334 are exposed. The openings 338 may be via openings that are smaller in dimensions compared to the openings 328 (FIG. 3C), which may be trenches.

As shown in FIG. 3E, the pattern of the photoresist layer 336 is transferred to the middle layer 334 and the bottom layer 332. In some embodiments, the portions of the bottom layer 332 and middle layer 334 are removed by two etch processes for the openings 338 to be transferred thereto. For example, the exposed portions of the middle layer 334 are first removed by a first etch process to expose portions of the bottom layer 332, and the exposed portions of the bottom layer 332 are removed by a second etch process. In some embodiments, the openings 338 formed in the photoresist layer 336 may be slightly misaligned with the portion of the bottom layer 332 disposed between the mask structure 320. However, because the etch selectivity between the bottom layer 332 and the first and second layers 322, 324 are substantially different, the portions of the dielectric layer 318 exposed in the openings 338 have substantially the same critical dimension (CD), regardless of whether misalignment occurred. Thus, the overlay tolerance T of the openings 338 may be higher, such as a from about 2 nm to about 3 nm, and the CD of the openings 338 in the dielectric layer 318 remain substantially uniform. In other words, even if misalignment occurs due to overlay, the CD of the openings 338 in the dielectric layer 318 is not substantially affected as a result of large overlay tolerance T.

As shown in FIG. 3F, the openings 338 are extended into the dielectric layer 318 by removing portions of the dielectric layer 318. The portions of the dielectric layer 318 may be removed by an etch process, such as a dry etch process. The etch process may be a selective etch process that does not substantially affect the first layer 322 and the second layer 324. The openings 338 formed in the dielectric layer 318 does not extend through the dielectric layer 318. As shown in FIG. 3F, the bottom 340 of the opening 338 formed in the dielectric layer 318 is a distance D away from the second etch stop layer 316. In some embodiments, the distance D ranges from about 5 percent to about 10 percent of the thickness of the dielectric layer 318. The portions of the dielectric layer 318 disposed below the openings 338 are subsequently removed to form via openings. Thus, if the distance D is less than about 5 percent of the thickness of the dielectric layer 318, the subsequently formed via openings may have larger critical dimension. On the other hand, if the distance D is greater than about 10 percent of the thickness of the dielectric layer 318, the via openings may not extend through the dielectric layer 318.

As shown in FIG. 3G, the multilayer structure 330 is removed. The multilayer structure 330 may be removed by one or more etch processes. For example, a first etch process is performed to remove the photoresist layer 336 (FIG. 3F), a second etch process is performed to remove the middle layer 334 (FIG. 3F), and a third etch process is performed to remove the bottom layer 332 (FIG. 3F). The etch processes may be selective etch processes, so the mask structure 320 and the dielectric layer 318 are not substantially affected. As a result of the etch processes, the openings 328 are formed in the first and second layers 322, 324. As described above, the openings 328 are trenches, while the openings 338 formed in the dielectric layer 318 are via openings.

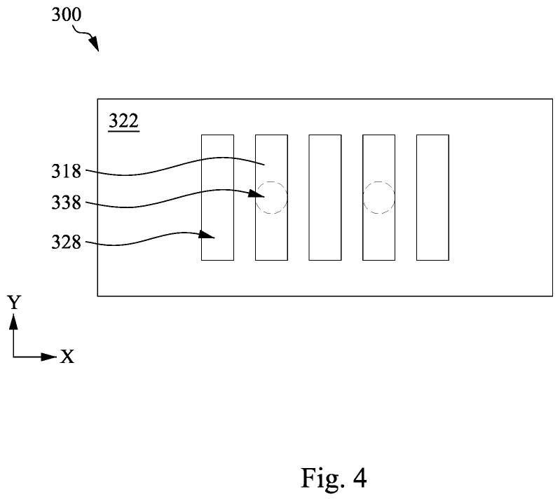

FIG. 4 is a cross-sectional top view of the interconnect structure 300 along cross-section A-A shown in FIG. 3G, in accordance with some embodiments. As shown in FIG. 4, the openings 328, which may be trenches, are formed in the first layer 322, and the portions of the dielectric layer 318 are exposed in the openings 328. The openings 338, which may be via openings, are formed in the dielectric layer 318.

Referring back to FIG. 3H, the openings 328, which may be trenches, are extended into the dielectric layer 318, and the openings 338, which may be via openings, are extended through the dielectric layer 318 to expose portions of the second etch stop layer 316. Furthermore, portions of the openings 338 initially formed in the dielectric layer 318 are turned into the openings 328. In other words, portions of the via openings (openings 338) initially formed in the dielectric layer 318, as shown in FIG. 3G, are enlarged to become trenches (openings 328) formed in the dielectric layer 318, as shown in FIG. 3H. As a result, the openings 328 (trenches) and the openings (338) are formed in the dielectric layer 318 simultaneously. The extending of the openings 328 from the first layer 322 into the dielectric layer 318, the changing of the portions of the openings 338 to the openings 328, and the extending of the openings 338 through the dielectric layer 318 to expose portions of the second etch stop layer 316 are performed by a single etch process. For example, the etch process removes portions of the dielectric layer 318 to form the openings 328 in the dielectric layer 318 and to extend the openings 338 through the dielectric layer 318. As described in FIG. 3F, because the distance D between the bottom 340 and the second etch stop layer 316 is about 5 percent to about 10 percent of the thickness of the dielectric layer 318, the openings 338 simultaneously formed with the openings 328 have relatively small bottom critical dimension CD2. Furthermore, because the final openings 328, 338 shown in FIG. 3H are formed by removing the portions of the dielectric layer 318, the etch time is shorter compared to the process that forms openings 328, 338 by removing portions of the first layer 322 and portions of the dielectric layer 318. For example, in another embodiment, the multilayer structure 330 is formed on the interconnect structure 300 shown in FIG. 3B, and then via openings are formed in the first layer 322 and the dielectric layer 318 by one or more etch processes. The trenches are then formed in the first layer 322 and the dielectric layer 318 by one or more etch processes. Because different materials and more materials are removed by the processes to form the openings 328, 338 in the dielectric layer 318, the etch time is longer and may cause over etching, leading to enlarged via opening bottom critical dimension and enlarged via opening angle. Thus, the process of forming the openings 328 in the first layer before forming the initial openings 338 in the dielectric layer 318, such as the process shown in FIGS. 3C to 3F, helps to reduce the bottom critical dimension CD2, to reduce via opening angle A, and to enlarge the via opening path. In some embodiments, the via opening angle A ranges from about 115 degrees to about 120 degrees. If the via opening angle A is outside of the range described above, the bottom critical dimension CD2 may be too large, leading to reduced breakdown voltage of the dielectric layer 318.

As shown in FIG. 3I, one or more etch processes are performed to remove portions of the second etch stop layer 316 and portions of the first etch stop layer 314 to expose portions of the conductive feature 312. The one or more etch processes may be selective etch processes that do not substantially affect the dielectric layer 318.

As shown in FIG. 3J, the mask structure 320 is removed, barrier layers 342 are formed in the openings 328, 338, and conductive features 344 are formed on the barrier layers 342. The mask structure 320 may be removed by any suitable process. The barrier layer 342 may include an electrically conductive material, such as a metal or metal nitride, and the conductive feature 344 may include the same material as the conductive feature 312. The conductive feature 344 includes a first portion 346 formed in each opening 338 and a second portion 348 formed in each opening 328. The second portion 348 of the conductive feature 344 formed in the openings 328 may be conductive lines, and the first portion 346 of the conductive feature 344 formed in the openings 338 may be conductive vias. The first portion 346 has smaller dimensions than dimensions of the second portion 348. A planarization process, such as a chemical mechanical polishing (CMP) process, may be performed to planarize the top surface of the interconnect structure 300 shown in FIG. 3J. The process described in FIGS. 3A to 3J is utilized to form conductive features, such as conductive lines and vias, and the process may be an improved dual damascene process.

The present disclosure in various embodiments provides a method to form conductive features in a dielectric layer. The method may be a dual damascene process. In some embodiments, the method includes forming openings 328 in a first layer 322 disposed on a dielectric layer 318, then forming openings 338 in the dielectric layer 318, and then simultaneously extending the openings 328 from the first layer 322 to the dielectric layer 318 and extending the openings 338 through the dielectric layer 318. Some embodiments may achieve advantages. For example, the process of forming the openings 328 in the first layer before forming the initial openings 338 in the dielectric layer 318 helps to reduce the bottom critical dimension CD2, to reduce via opening angle A, and to enlarge the via opening path.

An embodiment is a method. The method includes forming a mask structure on a dielectric layer, and the mask structure includes a first layer disposed on the dielectric layer, a second layer disposed on the first layer, and a third layer disposed on the second layer. The method further includes forming first openings having first dimensions in the first layer and forming a multilayer structure over the first layer. The multilayer structure includes a bottom layer disposed in the first openings and over the first layer, a middle layer disposed on the bottom layer, and a photoresist layer disposed on the middle layer. The bottom layer includes a material different from materials of the first, second, and third layers. The method further includes forming second openings having second dimensions in the bottom layer to expose portions of the dielectric layer, and the second dimensions are smaller than the first dimensions. The second openings each has an overlay tolerance ranging from about 2 nm to about 3 nm. The method further includes extending the second openings into the dielectric layer.

Another embodiment is a method. The method includes forming first openings having first dimensions in a first layer disposed on a dielectric layer, forming a second layer in the first openings and over the first layer, and forming second openings having second dimensions in the second layer to expose portions of the dielectric layer. The second dimensions are smaller than the first dimensions. The method further includes extending the second openings into the dielectric layer, removing the second layer, and simultaneously extending the first openings into the dielectric layer and extending the second openings through the dielectric layer. A portion of the second openings are turned into the first openings. Each second opening has an opening angle ranging from about 115 degrees to about 120 degrees. The method further includes forming second conductive features in the first and second openings in the dielectric layer. Each second conductive feature includes a first portion disposed over a second portion, and the first portion has dimensions larger than dimensions of the second portion.

A further embodiment is a method. The method includes forming a mask structure on a dielectric layer, and the mask structure includes a first layer disposed on the dielectric layer, a second layer disposed on the first layer, and a third layer disposed on the second layer. The method further includes forming first openings having first dimensions in the first layer, forming a fourth layer in the first openings and over the first layer, and forming second openings having second dimensions in the fourth layer to expose portions of the dielectric layer. The second dimensions are smaller than the first dimensions. The method further includes extending the second openings into the dielectric layer, the second openings each has a bottom that is a distance away from an etch stop layer disposed under the dielectric layer, and the distance is about 5 percent to about 10 percent of a thickness of the dielectric layer. The method further includes removing the second layer and simultaneously extending the first openings into the dielectric layer and extending the second openings through the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a mask structure on a dielectric layer, wherein the mask structure comprises a first layer disposed on the dielectric layer, a second layer disposed on the first layer, and a third layer disposed on the second layer;
forming first openings having first dimensions in the first layer;
forming a multilayer structure over the first layer, wherein the multilayer structure comprises a bottom layer disposed in the first openings and over the first layer, a middle layer disposed on the bottom layer, and a photoresist layer disposed on the middle layer, wherein the bottom layer comprises a material different from materials of the first, second, and third layers;
forming second openings having second dimensions in the bottom layer to expose portions of the dielectric layer, wherein the second dimensions are smaller than the first dimensions, and wherein the second openings each has an overlay tolerance ranging from about 2 nm to about 3 nm; and
extending the second openings into the dielectric layer.

2. The method of claim 1, wherein the first layer comprises a first material, the second layer comprises a second material different from the first material, and the third layer comprises the first material.

3. The method of claim 2, wherein the first openings are trenches, and the second openings are via openings.

4. The method of claim 3, further comprising forming the first openings in the second and third layers prior to forming the first openings in the first layer.

5. The method of claim 4, wherein the first openings are formed in the third layer by a first process, and the first openings are formed in the first layer by a second process different from the first process.

6. The method of claim 5, wherein the first process is an inductively coupled plasm etch process, and the second process is a capacitively coupled plasm etch process.

7. The method of claim 1, further comprising forming the second openings in the photoresist layer and the middle layer prior to forming the second openings in the bottom layer.

8. The method of claim 7, wherein the bottom layer comprises chromium and the dielectric layer comprises SiOCH.

9. A method, comprising:
forming first openings having first dimensions in a first layer disposed on a dielectric layer;
forming a second layer in the first openings and over the first layer, wherein the first and second layers comprise different materials;
forming second openings having second dimensions in the second layer to expose portions of the dielectric layer; wherein the second dimensions are smaller than the first dimensions;
extending the second openings into the dielectric layer;
removing the second layer;
simultaneously extending the first openings into the dielectric layer and extending the second openings through the dielectric layer, wherein a portion of the second openings are turned into the first openings, and wherein each second opening has an opening angle ranging from about 115 degrees to about 120 degrees; and
forming second conductive features in the first and second openings in the dielectric layer, wherein each second conductive feature includes a first portion disposed over a second portion, and the first portion has dimensions larger than dimensions of the second portion.

10. The method of claim 9, wherein the first openings are trenches, and the second openings are via openings.

11. The method of claim 10, further comprising removing the first layer after simultaneously extending the first openings into the dielectric layer and extending the second openings through the dielectric layer.

12. The method of claim 11, further comprising:
forming a first etch stop layer;
forming a second etch stop layer on the first etch stop layer;
forming the dielectric layer on the second etch stop layer;
forming the first layer on the dielectric layer;
forming a third layer on the first layer; and
forming a fourth layer on the third layer.

13. The method of claim 12, wherein the fourth layer is removed during the forming the first openings in the first layer.

14. The method of claim 12, further comprising removing portions of a first etch stop layer and portions of a second etch stop layer to expose portions of a first conductive feature after removing the first layer.

15. The method of claim 14, further comprising forming barrier layers in the first and second openings in the dielectric layer, wherein at least some of the barrier layers are in contact with the first conductive feature.

16. The method of claim 15, wherein the first portion of the second conductive feature is a conductive line, and the second portion of the second conductive feature is a conductive via.

17. A method, comprising:
forming a mask structure on a dielectric layer, wherein the mask structure comprises a first layer disposed on the dielectric layer, a second layer disposed on the first layer, and a third layer disposed on the second layer;
forming first openings having first dimensions in the first layer;
forming a fourth layer in the first openings and over the first layer;
forming second openings having second dimensions in the fourth layer to expose portions of the dielectric layer; wherein the second dimensions are smaller than the first dimensions;
extending the second openings into the dielectric layer, wherein the second openings each has a bottom that is a distance away from an etch stop layer disposed under the dielectric layer, wherein the distance is about 5 percent to about 10 percent of a thickness of the dielectric layer;
removing the second layer; and
simultaneously extending the first openings into the dielectric layer and extending the second openings through the dielectric layer.

18. The method of claim 17, further comprising forming the first openings in the second and third layers prior to forming the first openings in the first layer.

19. The method of claim 18, wherein during the third layer is removed during the forming the first openings in the first layer.

20. The method of claim 19, wherein portions of the second layer are removed to form curved top portions during the forming the first openings in the first layer.
